(19) United States
(12) Patent Application Publication
(10) Pub. No.: US 2023/0282566 A1
(43) Pub. Date: Sep. 7, 2023

(54) SEMICONDUCTOR PACKAGE HAVING NEGATIVE PATTERNED SUBSTRATE AND METHOD OF MANUFACTURING THE SAME

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/074,512

(22) Filed: Dec. 5, 2022

(30) Foreign Application Priority Data
Mar. 7, 2022 (KR) 10-2022-0028659

(51) Int. Cl. H01L 23/498; H01L 23/31; H01L 23/00; H01L 23/40

(52) U.S. Cl. CPC H01L 23/49861; H01L 23/3121; H01L 23/3114; H01L 24/29; H01L 23/40

(57) ABSTRACT

The present invention relates to a semiconductor package having a negative patterned substrate and a method of manufacturing the same, and more particularly, to a semiconductor package having a negative patterned substrate and a method of manufacturing the same, wherein in the semiconductor package and the method of manufacturing the same, a molding resin may not flow to the outside of the negative patterned substrate so as to prevent the substrate from being contaminated and a negative space is filled with the molding resin so as to stably perform a molding process.

### CROSS-REFERENCE TO RELATED PATENT APPLICATION

This application claims the benefit of Korean Patent Application No. 10-2022-0028659, filed on Mar. 7, 2022, in the Korean Intellectual Property Office, the disclosure of which is incorporated herein in its entirety by reference.

### BACKGROUND OF THE INVENTION

### 1. Field of the Invention

The present invention relates to a semiconductor package having a negative patterned substrate and a method of manufacturing the same, and more particularly, to a semiconductor package having a negative patterned substrate and a method of manufacturing the same, wherein in the semiconductor package and the method of manufacturing the same, a molding resin may not flow to the outside of the negative patterned substrate so as to prevent the substrate from being contaminated and a negative space is filled with the molding resin so as to stably perform a molding process.

### 2. Description of the Related Art

In general, a semiconductor package includes a semiconductor chip installed on a lower substrate and/or an upper substrate, a conductor which is a metal post functioning as a spacer bonded to the semiconductor chip, a lead frame for applying an electrical signal from the outside, a package housing molded by a sealing member, and a heat release post exposed onto the lower substrate and/or the upper substrate. Here, while the package housing is molding, a mold presses a part of each heat release metal layer, for example, the edges thereof, without contacting the heat release post formed uprightly on the lower substrate and/or the upper substrate and thereby, the package housing is formed.

When the package housing is formed as described above, the pressure applied by the mold is not uniform and the pressure applying to the heat release metal layer is low. Accordingly, the molding resin may overflow onto the heat release metal layer and thus, the substrate may be contaminated so as to affect stability of the semiconductor package.

In this regard, uniform pressure needs to be made by the mold to prevent contamination of the substrate occurring due to the molding resin and to stably perform a molding process, and radiation fins having various forms and structures need to be applied to expand contact areas, so that there is a need for an improvement in thermal conductivity and heat radiation efficiency using a direct cooling method by a coolant.

### SUMMARY OF THE INVENTION

The present invention provides a semiconductor package having a negative patterned substrate and a method of manufacturing the same in which a molding resin may not flow to the outside of the negative patterned substrate so as to prevent the substrate from being contaminated and negative spaces are filled with the molding resin so as to stably perform a molding process.

According to an aspect of the present invention, there is provided a semiconductor package having a negative patterned substrate including: a negative patterned substrate which is penetrated in a negative form, includes a flat negative patterned bottom formed thereon, and is formed of a metal material; at least one insulating layer which is formed on the negative patterned bottom; a metal pattern layer which is formed on the insulating layer; at least one semiconductor chip which is installed on the metal pattern layer; electrical connecting members which electrically connect the metal pattern layers to the semiconductor chips; at least one terminal which is formed uprightly on the metal pattern layer and is extended to be exposed to the outside of the negative patterned substrate; and a molding sealing member which is filled in a negative space of the negative patterned substrate and is molded to cover the semiconductor chips, the electrical connecting members, and a part of the terminals, wherein upper ends of the at least one terminal are exposed to an upper part of the molding sealing member and thus, are electrically connected to external electrical connecting members.

The negative patterned substrate may be formed of a single material such as Al or Cu or an alloy containing 50% or more of any one of Al and Cu.

30% or more of the total surface area of the negative patterned substrate may be plated.

The negative patterned substrate may include a negative pattern depth in the range of 0.5 mm to 10 mm.

The insulating layer may include at least one metal layer formed on one surface thereof or one and the other surfaces thereof.

The negative patterned substrate and the insulating layer may be bonded to each other by using a bonding member interposed therebetween.

Here, the bonding member may be solder containing Sn or a containing Ag or Cu.

The insulating layers may be disposed on the negative patterned bottom in the form of paste or film and may be formed on the negative patterned substrate after a hardening process.

The metal pattern layers may have a thickness of 0.1 mm through 5 mm.

The semiconductor chips may include a power conversion function.

The electrical connecting members may be formed of a material containing Au, Al, or Cu.

The molding sealing member may be formed of a composite material containing epoxy content or an insulating material containing Si content.

The molding sealing member may have a thickness of above 1 mm.

The upper ends of the at least one terminal may be formed as female screws.

Here, the external electrical connecting members may be formed as male screws which are bolt-joined to the upper ends of the terminals and thereby, may be electrically connected to the terminals.

Longitudinal sections of the at least one terminal may be formed as press fit pins and may be electrically connected to the external electrical connecting members.

The negative patterned substrate may include at least one radiation fin structurally joined to the lower surface thereof.

The negative patterned substrate may include at least one wave-form metal plate structurally joined to the lower surface thereof.

The negative patterned substrate may include a cover for covering 50% or more of the total area of the molding sealing member formed on the upper part thereof and the terminals may penetrate the cover to be exposed to the upper part of the cover.

The negative patterned substrate may include a cooling system structurally joined thereto and a joining surface interposed between the negative patterned substrate and the cooling system may include substrate bonding members formed thereon to make a coolant of the cooling system watertight.

The negative patterned substrate may include a cooling system structurally joined thereto, and the negative patterned substrate and the cooling system may be joined to each other by using friction stir welding to make the coolant of the cooling system watertight.

According to another embodiment of the present invention, there is provided a method of manufacturing a semiconductor package having a negative patterned substrate including: preparing a negative patterned substrate which is penetrated in a negative form, includes a flat negative patterned bottom formed thereon, and is formed of a metal material; forming at least one insulating layer which is formed on the negative patterned bottom; forming a metal pattern layer which is formed on the insulating layer; installing at least one semiconductor chip on the metal pattern layer; electrically connecting the metal pattern layers to the semiconductor chips by using electrical connecting members; forming uprightly at least one terminal, which is extended to be exposed to the outside of the negative patterned substrate, on the metal pattern layer; and filling a negative space of the negative patterned substrate with a molding sealing member and molding to cover the semiconductor chips, the electrical connecting members, and a part of the terminals, wherein upper ends of the at least one terminal are exposed to an upper part of the molding sealing member and thus, are electrically connected to external electrical connecting members.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a semiconductor package having a negative patterned substrate according to an embodiment of the present invention;

FIG. 2 is a plan view of the semiconductor package having the negative patterned substrate of FIG. 1;

FIG. 3 illustrates radiation fins of the semiconductor package having the negative patterned substrate of FIG. 1;

FIG. 4 illustrates a modification example of the radiation fins of FIG. 3;

FIG. 5 illustrates a cover of FIG. 3;

FIG. 6A and FIG. 6B illustrate a combination structure of the semiconductor package having the radiation fins of FIG. 3 and a cooling system;

FIG. 7 is a flowchart schematically illustrating a method of manufacturing a semiconductor package having a negative patterned substrate according to another embodiment of the present invention; and

FIG. 8 is a cross-sectional view of a semiconductor package having a negative patterned substrate according to another embodiment of the present invention.

### DETAILED DESCRIPTION OF THE INVENTION

Hereinafter, embodiments of the present invention will be described in more detail with reference to the accompanying drawings.

A semiconductor package having a negative patterned substrate according to an embodiment of the present invention includes a negative patterned substrate 110, at least one insulating layer 120, a metal pattern layer 130, at least one semiconductor chip 140, electrical connecting members, at least one terminal 160, and a molding sealing member 170, wherein the negative patterned substrate 110 is penetrated in a negative form, includes a flat negative patterned bottom 111 formed thereon, and is formed of a metal material, the at least one insulating layer 120 is formed on the negative patterned bottom 111, the metal pattern layer 130 is formed on the insulating layer 120, the at least one semiconductor chip 140 is installed on the metal pattern layer 130, the electrical connecting members electrically connect the metal pattern layers 130 to the semiconductor chips 140, the at least one terminal 160 is formed uprightly on the metal pattern layer 130 and is extended to be exposed to the outside of the negative patterned substrate 110, and the molding sealing member 170 is filled in a negative space of the negative patterned substrate 110 and is molded to cover the semiconductor chips 140, the electrical connecting members, and a part of the terminals 160. Here, upper ends of the at least one terminal 160 are exposed to an upper part of the molding sealing member 170 and thus, are electrically connected to external electrical connecting members 10. Accordingly, the negative patterned substrate 110 may be prevented from being contaminated occurring due to a molding resin and a molding process may be stably performed.

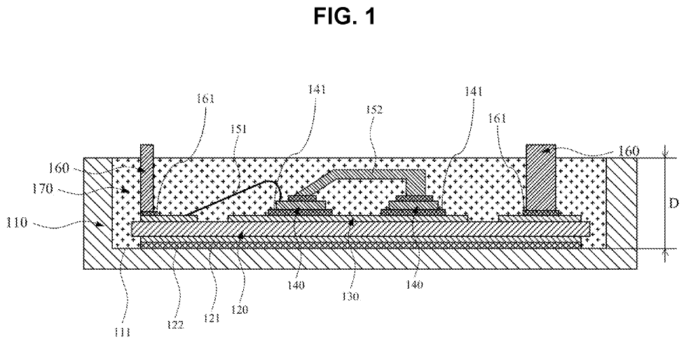

Hereinafter, the semiconductor package having the negative patterned substrate 110 above will be described in more detail with reference to FIGS. 1 through 6A, 6B and 8.

First, referring to FIGS. 1, 2, and 8, the negative patterned substrate 110 is formed of a metal material, includes an internal space penetrated thereinto in a negative form, and has an edge region having a certain height, wherein the internal space includes the flat negative patterned bottom 111.

On the other hand, the negative patterned substrate 110 may be formed of a single material having excellent electrical conductivity or thermal conductivity such as Al or Cu or an alloy containing 50% or more of any one of Al and Cu.

Also, 30% or more of the total surface area of the negative patterned substrate 110 is plated and thus, electrical conductivity or thermal conductivity may be raised.

In addition, as illustrated in FIG. 1, the negative pattern depth D of the negative patterned substrate 110 may be in the range of 0.5 mm to 10 mm.

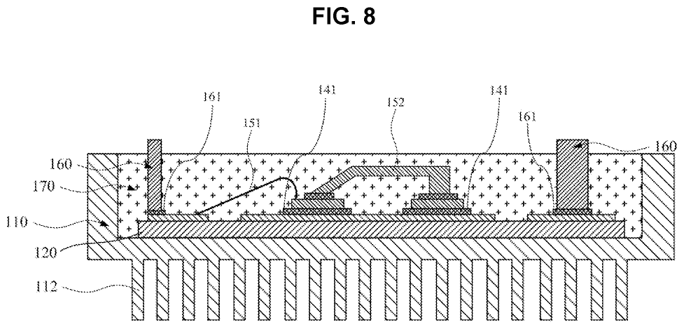

Next, referring to FIGS. 1 and 8, the insulating layer 120 may include one or more layers disposed on the negative patterned bottom 111 of the negative patterned substrate 110 and may be formed of a single material such as Al₂O₃, AlN, Si₃N₄, or SiC or a composite material including any one of Al₂O₃, AlN, Si₃N₄, and SiC.

At least one metal layer 121 may be formed on one surface or one and the other surfaces of the insulating layer 120 (refer to FIG. 1), and a bonding member 122 may be interposed between the negative patterned substrate 110 and the insulating layer 120 to be bonded to each other.

Here, the bonding member 122 may be solder containing Sn or a material (metal material) containing Ag or Cu.

Also, the insulating layers 120 may be disposed on the negative patterned bottom 111 in the form of paste or film and may be hardened on the negative patterned substrate 110 after a hardening process to have a constant thickness.

Next, the metal pattern layer 130 may include one or more layers disposed on the insulating layer 120 and may be electrically connected to the semiconductor chip 140.

Here, the metal pattern layers 130 may have a thickness of 0.1 mm through 5 mm.

Next, the at least one semiconductor chip 140 may be installed by using a bonding layer 141 formed on the metal pattern layers 130 and may be a power semiconductor chip including a power conversion function such as an Insulated Gate Bipolar Transistor (IGBT) or a Metal-Oxide-Semiconductor Field-Effect Transistor (MOSFET) which may be applied to devices such as an inverter, a converter, or an On Board Charger (OBC) used to convert or control power.

Next, the electrical connecting members electrically may connect the metal pattern layers 130 to the semiconductor chip 140 and/or the semiconductor chips 140 and may be a wire 151 or a face bonding type conductive clip 152.

Here, the electrical connecting members 151 and 152 may be formed of a material (metal material) containing Au, Al, or Cu which has excellent electrical conductivity.

Next, the at least one terminal 160 is formed uprightly on the metal pattern layers 130 in the form of posts by using bonding layers 161 interposed therebetween and is extended to be exposed to the outside of the negative patterned substrate 110 so that an electrical signal may be applied from the outside.

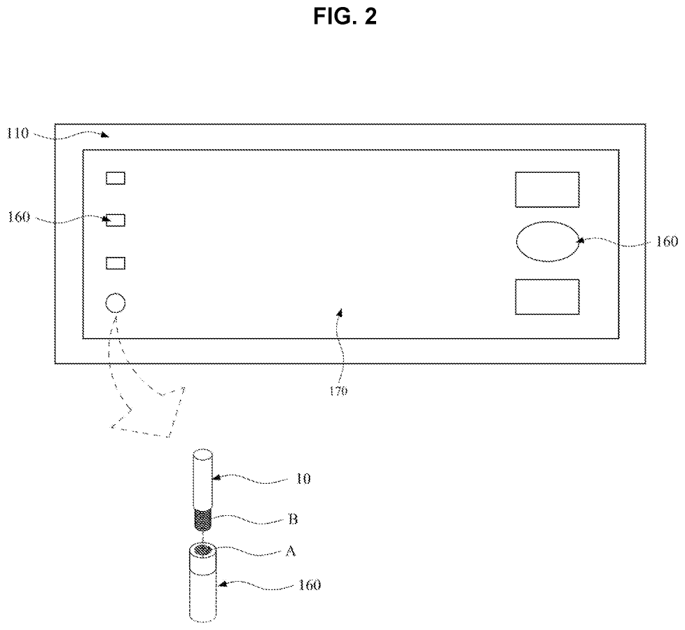

As illustrated in FIG. 2, the upper ends of the at least one terminal 160 may be formed as female screws A and the external electrical connecting members 10 may be formed as male screws B which are bolt-joined to the upper ends of the terminals 160. Accordingly, the terminals 160 and the external electrical connecting members 10 may be joined to each other and may be electrically connected to each other.

Also, although not illustrated, longitudinal sections of the at least one terminal 160 may be formed as press fit pins and may be pressed to electrically connect to the external electrical connecting members.

Next, the molding sealing member 170 is formed of EMC, PBT, or PPS, is filled in the negative space of the negative patterned substrate 110, covers and insulates the semiconductor chips 140, the electrical connecting members 151 and 152, and a part of the terminals 160, and is molded to cover and protect a part of an internal circuit.

More preferably, the molding sealing member 170 may be formed of a composite material containing epoxy content or an insulating material containing Si content and may have a thickness of above 1 mm.

Here, as illustrated in FIGS. 1, 2, and 8, the upper ends of the at least one terminal 160 are exposed to the upper part of the molding sealing member 170 and may be electrically joined to the external electrical connecting members 10.

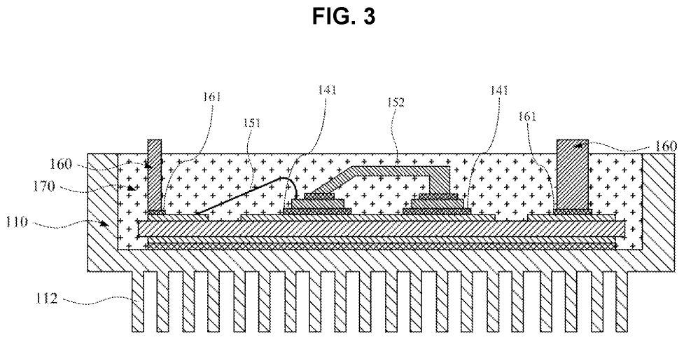

On the other hand, as illustrated in FIG. 3, at least one radiation fin 112 is structurally joined to the lower surface of the negative patterned substrate 110 so that heat transmitted to the negative patterned substrate 110 may be radiated to the outside and thus, operating reliability of the semiconductor chips 140 may be secured.

Here, the radiation fins 112 may have various forms such as circular columns, elliptical columns, or polygonal columns and may be formed in such a way that the negative patterned substrate 110 is masked using a screen mask or a stencil mask and a metal paste or a non-metal paste is directly printed on the negative patterned substrate 110 and is hardened. Accordingly, the negative patterned substrate 110 and the radiation fins 112 may be directly joined to each other without additional bonding layers and thereby, may have a combined structure.

Also, the radiation fins 112 may be formed of a metal having excellent thermal conductivity, may contain 40% or more of metal component having excellent thermal conductivity, or may be formed of a material which is same as that of the negative patterned substrate 110.

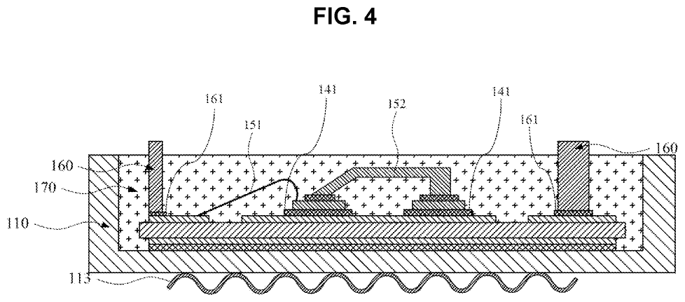

In addition, as illustrated in FIG. 4, at least one wave-form metal plate 113 may be structurally joined to the lower surface of the negative patterned substrate 110 by using ultrasonic welding so that heat transmitted to the negative patterned substrate 110 may be radiated to the outside and thus, operating reliability of the semiconductor chips 140 may be secured.

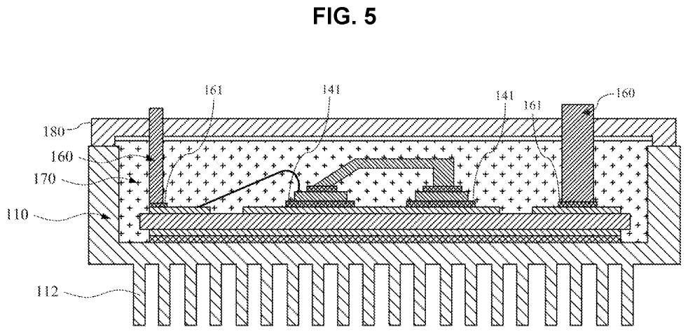

As illustrated in FIG. 5, a cover 180 for covering 50% or more of the total area of the molding sealing member 170 is formed on the upper part of the negative patterned substrate 110 to protect the molding sealing member 170 from being damaged. The terminals 160 may penetrate the cover 180 to be exposed to the upper part of the cover 180 and may be electrically connected to the external electrical connecting members 10. Also, the at least one radiation fins 112 may be structurally joined to the lower surface of the negative patterned substrate 110.

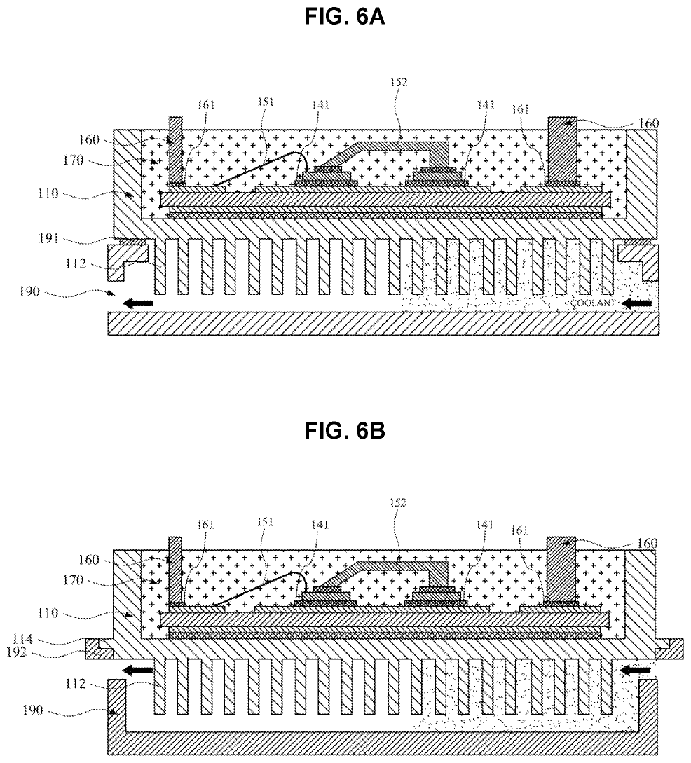

As illustrated in FIG. 6A, a cooling system 190 is structurally joined to the negative patterned substrate 110 and substrate bonding members 191, which are in the form of an oil ring or an adhesive to make a coolant of the cooling system 190 watertight, are formed on joining surfaces interposed between the lower part of the negative patterned substrate 110 and the upper part of the cooling system 190. Accordingly, the radiation fins 112 may be cooled using the coolant and thereby, heat radiation efficiency may be increased.

As illustrated in FIG. 6B, the cooling system 190 is structurally joined to the negative patterned substrate 110, and the lower part of the negative patterned substrate 110 and the upper grooves 192 of the cooling system 190 are joined to each other at lower skirts 114 of the negative patterned substrate 110 by using friction stir welding (FSW) to make the coolant of the cooling system 190 watertight. Accordingly, the radiation fins 112 may be cooled using the coolant and thereby, heat radiation efficiency may be increased.

Here, the coolant may directly contact the radiation fins 112 so as to expand a contact surface with the coolant and thereby, heat radiation efficiency may be improved. Here, the coolant may include cooling water, a coolant fluid, refrigerant gas, or air. However, the present invention is not limited thereto, and the coolant may include all kinds of refrigerant which is cold. Also, a cooling method may be water cooling or air cooling.

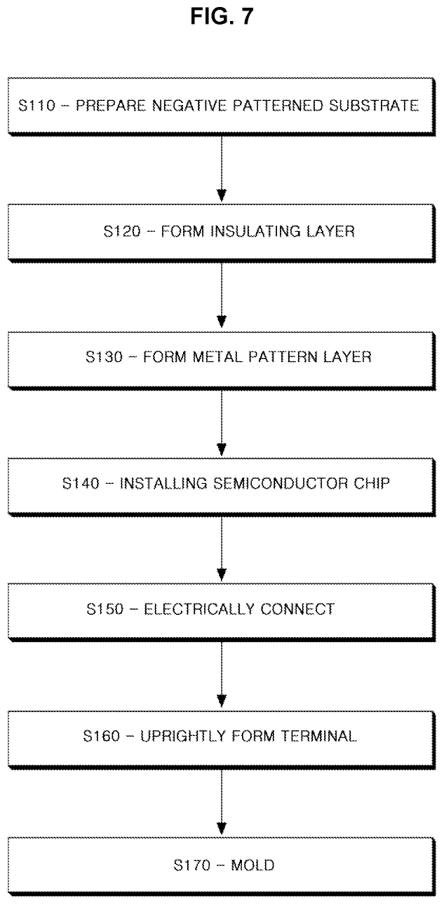

FIG. 7 is a flowchart schematically illustrating a method of manufacturing a semiconductor package having a negative patterned substrate according to another embodiment of the present invention.

First, the negative patterned substrate 110 is prepared in operation S110, wherein the negative patterned substrate 110 is penetrated in a negative form, includes the flat negative patterned bottom 111 formed thereon, and is formed of a metal material.

Then, the at least one insulating layer 120 is formed on the negative patterned bottom 111 in operation S120.

Then, the metal pattern layers 130 are formed on the insulating layers 120 in operation S130.

Then, the at least one semiconductor chip 140 is installed on the metal pattern layers 130 in operation S140.

Then, the metal pattern layers 130 and the semiconductor chips 140 are electrically connected to each other by using the electrical connecting members in operation S150.

Then, the at least one terminal 160, which is extended to be exposed to the outside of the negative patterned substrate 110, is uprightly formed on the metal pattern layers 130 in operation S160.

Then, the molding sealing member 170 is filled in the negative space of the negative patterned substrate 110 and is molded to cover the semiconductor chips 140, the electrical connecting members, and a part of the terminals 160 in operation S170.

Here, according to the method of manufacturing the semiconductor package, wherein in the semiconductor package, the upper ends of the at least one terminal 160 are exposed to an upper part of the molding sealing member 170 and thus, are electrically connected to the external electrical connecting members, the outside of the negative patterned substrate 110 may be prevented from being contaminated occurring due to a molding resin and a molding process may be stably performed.

Here, the negative pattern depth of the negative patterned substrate 110 may be in the range of 0.5 mm to 10 mm.

Also, as illustrated in FIG. 2, the upper ends of the at least one terminal 160 may be formed as female screws A and the external electrical connecting members 10 may be formed as male screws B which are bolt-joined to the upper ends of the terminals 160. Accordingly, the terminals 160 and the external electrical connecting members 10 may be joined to each other and may be electrically connected to each other.

Also, although not illustrated, longitudinal sections of the at least one terminal 160 may be formed as press fit pins and may be pressed to electrically connect to the external electrical connecting members.

Therefore, in the semiconductor package having a negative patterned substrate and the method of manufacturing the same described above, a molding resin may not flow to the outside of the negative patterned substrate so as to prevent the substrate from being contaminated and the negative space is filled with the molding resin so as to stably perform a molding process.

According to the present invention, the molding resin may not flow to the outside of the negative patterned substrate so as to prevent the substrate from being contaminated and the negative space is filled with the molding resin so as to stably perform a molding process. Also, the radiation fins having various forms and structures may be used to expand an area contacting the coolant and thereby, heat generated from the semiconductor chip may be efficiently cooled.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package having a negative patterned substrate comprising:
a negative patterned substrate which is penetrated in a negative form, comprises a flat negative patterned bottom formed thereon, and is formed of a metal material;
at least one insulating layer which is formed on the negative patterned bottom;
a metal pattern layer which is formed on the insulating layer;
at least one semiconductor chip which is installed on the metal pattern layer;
electrical connecting members which electrically connect the metal pattern layers to the semiconductor chips;
at least one terminal which is formed uprightly on the metal pattern layer and is extended to be exposed to the outside of the negative patterned substrate; and
a molding sealing member which is filled in a negative space of the negative patterned substrate and is molded to cover the semiconductor chips, the electrical connecting members, and a part of the terminals,
wherein upper ends of the at least one terminal are exposed to an upper part of the molding sealing member and thus, are electrically connected to external electrical connecting members.

2. The semiconductor package of claim 1, wherein the negative patterned substrate is formed of a single material such as Al or Cu or an alloy containing 50% or more of any one of Al and Cu.

3. The semiconductor package of claim 1, wherein 30% or more of the total surface area of the negative patterned substrate is plated.

4. The semiconductor package of claim 1, wherein the negative patterned substrate comprises a negative pattern depth in the range of 0.5 mm to 10 mm.

5. The semiconductor package of claim 1, wherein the insulating layer comprises at least one metal layer formed on one surface thereof or one and the other surfaces thereof.

6. The semiconductor package of claim 1, wherein the negative patterned substrate and the insulating layer are bonded to each other by using a bonding member interposed therebetween.

7. The semiconductor package of claim 1, wherein the insulating layers are disposed on the negative patterned bottom in the form of paste or film and are formed on the negative patterned substrate after a hardening process.

8. The semiconductor package of claim 1, wherein the metal pattern layers have a thickness of 0.1 mm through 5 mm.

9. The semiconductor package of claim 1, wherein the semiconductor chip comprises a power conversion function.

10. The semiconductor package of claim 1, wherein the electrical connecting members are formed of a material containing Au, Al, or Cu.

11. The semiconductor package of claim 1, wherein the molding sealing member is formed of a composite material containing epoxy content or an insulating material containing Si content.

12. The semiconductor package of claim 1, wherein the molding sealing member has a thickness of above 1 mm.

13. The semiconductor package of claim 1, wherein the upper ends of the at least one terminal are formed as female screws.

14. The semiconductor package of claim 1, wherein longitudinal sections of the at least one terminal are formed as press fit pins and are electrically connected to the external electrical connecting members.

15. The semiconductor package of claim 1, wherein the negative patterned substrate comprises at least one radiation fin structurally joined to the lower surface thereof.

16. The semiconductor package of claim 1, wherein the negative patterned substrate comprises at least one wave-form metal plate structurally joined to the lower surface thereof.

17. The semiconductor package of claim 1, wherein the negative patterned substrate comprises a cover for covering 50% or more of the total area of the molding sealing member formed on the upper part thereof and the terminals penetrate the cover to be exposed to the upper part of the cover.

18. The semiconductor package of claim 1, wherein the negative patterned substrate comprises a cooling system structurally joined thereto and a joining surface interposed between the negative patterned substrate and the cooling system comprises substrate bonding members formed thereon to make a coolant of the cooling system watertight.

19. The semiconductor package of claim 1, wherein the negative patterned substrate comprises a cooling system structurally joined thereto, and the negative patterned substrate and the cooling system are joined to each other by using friction stir welding to make the coolant of the cooling system watertight.

20. A method of manufacturing a semiconductor package having a negative patterned substrate, the method comprising:
preparing a negative patterned substrate which is penetrated in a negative form, comprises a flat negative patterned bottom formed thereon, and is formed of a metal material;
forming at least one insulating layer which is formed on the negative patterned bottom;
forming a metal pattern layer which is formed on the insulating layer;
installing at least one semiconductor chip on the metal pattern layer;
electrically connecting the metal pattern layers to the semiconductor chips by using electrical connecting members;
forming uprightly at least one terminal, which is extended to be exposed to the outside of the negative patterned substrate, on the metal pattern layer; and
filling a negative space of the negative patterned substrate with a molding sealing member and molding to cover the semiconductor chips, the electrical connecting members, and a part of the terminals,
wherein upper ends of the at least one terminal are exposed to an upper part of the molding sealing member and thus, are electrically connected to external electrical connecting members.
